(19) United States
(12) Patent Application Publication
(10) Pub. No.: US 2008/0224686 A1
(43) Pub. Date: Sep. 18, 2008

(54) System and method for remotely identifying a connected RF cable

(76) Inventor: Christian Boucher, Mascouche (CA)

Correspondence Address: Franz BONSANG;c/o PROTECTIONS EQUINOX INT'L INC., Suite 224, 4480, Cote-de-Liesse, Montreal, QC, H4N 2R1, CA

(21) Appl. No.: 11/717,070

(22) Filed: Mar. 13, 2007

(51) Int. Cl. G01R 19/00

(52) U.S. Cl. 324/66

(57) ABSTRACT

A system and method is provided for identifying, among a plurality of cables having respective first and second cable end portions, a connected cable connected to a selected antenna without interrupting service thereof. A signal emitter is connected to the respective first cable end portion, proximal the selected antenna, of the connected cable. A signal meter is connected to the respective second end portion of each cable. A signal is emitted from the signal emitter and the respective received signal amplitude of the signal received at the second respective cable end portion is measured. The cable for which the respective received signal amplitude of the signal received at the second respective cable end portion is greatest is the connected cable.

### FIELD OF THE INVENTION

The present invention relates to maintenance of antennas, and is more particularly concerned with a method and system for remotely identifying cables connected to antennas in wireless communication networks.

### BACKGROUND OF THE INVENTION

Systems and methods for installing and performing maintenance, such as upgrades, on communications networks, including wireless telecommunications networks, such as cellular telephone networks, are well known in the art. Such methods and systems are typically conceived for minimizing, and preferably completely avoiding, loss of service on the telecommunications networks during maintenance thereof, which is costly to service providers operating the networks. Further, service providers must generally avoid or minimize service outages to ensure compliance with regulations and standards governing the telecommunications industry. To further reduce impact of installation and maintenance operations on service, service providers typically perform such operations during periods of low network traffic, such as between midnight and 6 a.m. Performance of installation and maintenance operations during such periods, however, can be costly from a labor perspective.

At the same time, competition for customers, notably in the domain of wireless telecommunications, has increased significantly in recent years. Accordingly, to minimize costs and outages, both of which may negatively impact customer loyalty and sales, service providers have endeavored to reduce the cost and the amount of time required for maintenance and installation operations, as well as any outages resulting therefrom. In particular, for wireless telecommunications networks, service providers have endeavored to ensure that installation and maintenance of wireless antenna stations, such as cellular base stations, are effected as quickly as possible. Notably, service providers have attempted to connect the antennas of the stations, typically situated on top of buildings or towers, via cables to interfaces to the communications networks as quickly as possible to ensure that wireless connectivity to the network is quickly established and/or restored. These interfaces to the networks are often situated remote from the antennas, for example at the bottom of a tower or inside buildings.

The rapidity with which the antennas have been traditionally connected to the networks has often led to incomplete or erroneous installation or maintenance. For example, due to the hurry to put the wireless antenna stations into service, sometimes only a portion of the antennas on the station are actually connected to the RF (Radio-Frequency) cables required to connect the antennas to the network. Also, haste in getting the station into service also results in some antennas being connected to the cables, on a first cable end thereof, but failure to connect the cables, on a second end thereof, to the network. Further, and perhaps most importantly, attempts to put the stations into service as quickly as possible has often led to incorrect, or omission of, record keeping as to which cable is connected to which antenna, if any, especially in the case of stations having multiple antennas. This problem is further compounded by the fact that the antennas are generally connected to the cables on first cable ends thereof which are situated remotely from the interface at which the cables are connected, on a second ends thereof, to the network, which makes tracing of the cables to the antennas visually or by hand difficult, if not impossible. The fact that the cables often extend through a structure, such as conduits leading to the towers, and within which the cables are grouped together and cannot easily be viewed or separated from one another, further complicates this issue. However, since the stations, and antennas thereof, require ongoing maintenance and it is desirable to ensure that all antennas are connected to the network to ensure maximum connectivity for customers, identification of the cables to which the antennas are connected is essential.

Accordingly, there is a need for an improved method and system for remotely identifying a cable to which a selected antenna is connected.

### SUMMARY OF THE INVENTION

It is therefore a general object of the present invention to provide an improved method and system for remotely identifying a cable to which a selected antenna is connected.

An advantage of the present invention is that the cable can be identified quickly, without having to trace the cables manually or visually without disconnecting an end of the cable and without interruption of the service provided therewith.

Another advantage of the present invention is that the cable can be identified remotely from the respective cable end to which the selected antenna is connected.

A further advantage of the present invention is that the present invention permits identification of the cable connected to the selected antenna with a high degree of accuracy.

In a first aspect of the present invention, there is a provided a method for remotely identifying a connected cable among a plurality of cables having respective first cable end portions situated proximal a selected antenna and generally opposed second cable end portions connected to a communication network for communication service therealong and being interconnected to one another by at least one ground connector connected to each cable, the connected cable being connected on the respective first end portion thereof to the selected antenna, the method comprising the steps of:
a) emitting at least one signal on the respective first end portion of the connected cable, the signal being transferred therefrom to the other cables at the ground connector and carried by all cables to their respective second cable end portions;
b) for each cable, measuring a respective received signal amplitude of the signal at the respective second cable end portion thereof, the respective received signal amplitude for each cable being diminished as the signal passes through the ground connector; and
c) identifying the connected cable at the respective second cable end portion thereof as the cable for which the respective received signal amplitude is greatest, the signal traveling on a more direct path on the connected cable from the first respective cable end portion through the ground connector to the second respective cable end portion thereof than on the other cables, the respective received signal amplitude being thereby diminished less than for the other cables.

In a second aspect of the present invention, there is provided a system for remotely identifying a connected cable of a plurality of cables having respective first cable end portions situated proximal a selected antenna and generally opposed second cable end portions connected to a communication network for communication service therealong and being interconnected to one another by at least one ground connector connected to each cable, the connected cable being connected on the respective first end thereof to the selected antenna, the system comprising:
a signal emitter for emitting a signal on the respective first end portion of the connected cable, the signal being transferred therefrom to each other cable at the ground connector; and
a signal meter connectable to each cable for measuring a respective received signal amplitude for the signal on the respective second cable end portion thereof, the cable for which the respective received signal amplitude being the connected cable, wherein the connected cable provides a more direct path from the first respective cable end portion to the second respective cable end portion and the respective received signal amplitude for each cable is diminished as the signal is transferred thereto at the ground connector, the connected cable being identified as the cable for which the respective receiving signal amplitude is greatest.

Other objects and advantages of the present invention will become apparent from a careful reading of the detailed description provided herein, with appropriate reference to the accompanying drawings.

### BRIEF DESCRIPTION OF THE DRAWINGS

Further aspects and advantages of the present invention will become better understood with reference to the description in association with the following Figures, in which similar references used in different Figures denote similar components, wherein:

FIG. 1 is a view of a system for identifying a cable to which a selected antenna is connected;

FIG. 2 is a flowchart presenting a method for identifying a cable to which a selected antenna is connected; and

FIG. 3 is a flowchart presenting the method shown in FIG. 3 in greater detail.

### DETAILED DESCRIPTION OF THE PREFERRED EMBODIMENTS

With reference to the annexed drawings the preferred embodiments of the present invention will be herein described for indicative purpose and by no means as of limitation.

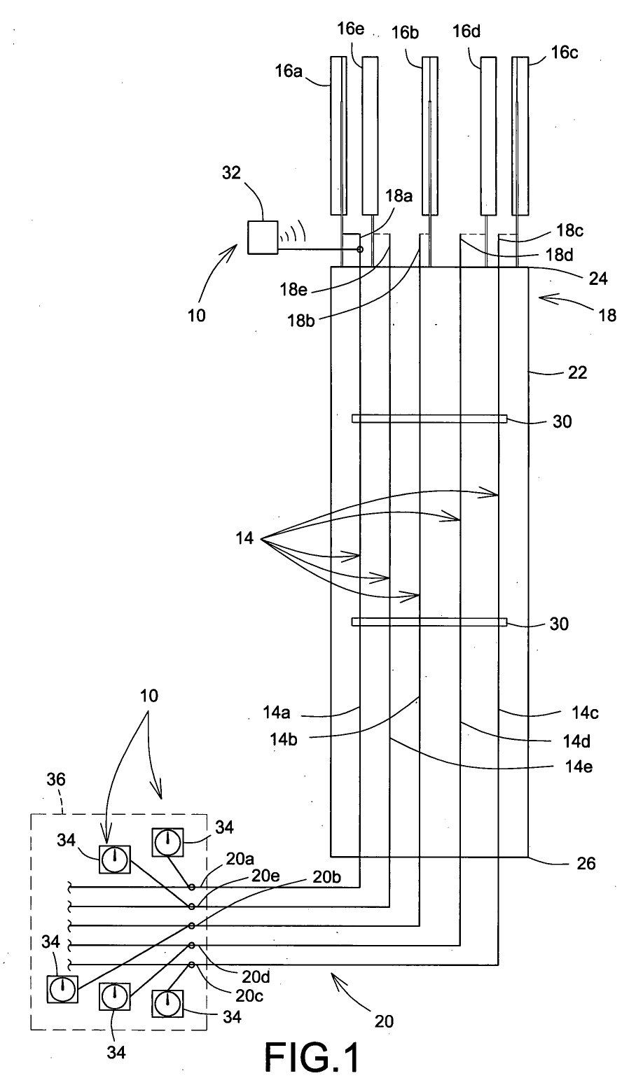

Reference is now made to FIG. 1, which shows a system, shown generally as 10, for remotely, without disconnection, identifying a connected cable 14a, possibly among a plurality of cables 14, connected to a selected antenna 16a, possibly among a plurality of antennas 16. The cables 14 have respective first cable end portions 18, which are situated proximal the antennas 16 and are connectable thereto, and generally opposed respective second cable end portions 20 situated remotely from the antennas 16. The cables 14 are generally interconnected to each other by at least one ground connector 30 situated intermediate the respective first cable end portions 18 and respective second cable end portions 20. The cables 14 may be cables 14 configured for carrying telecommunications signals to and from the antennas 16 from a telecommunications network, not shown, with the antennas 16 sending and receiving telecommunications signals to and from wireless transceiver devices, not shown, such as cellular telephones, personal digital assistants, and computing devices enabled with wireless networking capabilities. The cables 14 typically extend through or along a structure 22, such as a tower, tube, conduit, or wall of a building, with the first respective cable end portions 18 being situated proximal to and, possibly extending out of, a top end 24 of the structure 22. The second respective cables end portions 20 are situated proximal to, and possibly extend from, a bottom end 26 of the structure 22, generally opposed to the top end 24 thereof, typically to connect to the communication network at a radio cabinet 36 or the like (shown in dotted lines in FIG. 1). The antennas 16 are typically mounted on the top end 24 of the structure 22. Preferably, for cables 14 connecting antennas 16 to telecommunications networks, there is a ground connector 30 connected to the cables 14 at spaced intervals varying between about fifteen to about sixty feet (15-60 ft), 5-20 meters, depending on the cable type and the length thereof.

The system 10 includes at least one signal emitter 32 and at least one signal meter 34. The signal emitter 32 is remotely connectable to, typically clipped around or encircling and in a proximity and spaced apart (as identified by an empty circle over a solid line in FIG. 1), the respective first cable end portions 18 of the cables 14. Alternatively, the signal emitter 32 may be remotely connectable to the antennas 16. The signal meter 34 is remotely connectable to, and typically spaced apart or encircling and in a proximity and spaced apart (as identified by an empty circle over a solid line in FIG. 1), the respective second cable end portions 20. The signal emitter 32 is configured to emit a signal at a configurable pre-determined frequency carriable by the cables 14 from the respective first cable end portions 18 thereof to the respective second cables end portions 20 and, if desired, from the antenna 16 through the cables 14 if the signal emitter 32 is connected to the first cable end portion 18. More specifically, the signal emitter 32 is connected proximal to the respective first cable end portion 18a of the connected cable 14a, i.e. the cable 14a connected to a selected antenna 16a for which one wishes to identify the cable 14a connected thereto at the respective second cable end portion 20a thereof, as shown in FIG. 1, and emits the signal therefrom. The signal is then carried through the connected cable 14a to the respective second cable end portion 20a. While the signal is carried through the connected cable 14a it is also transferred to all of the other cables 14b,c,d,e at the ground connector 30 interconnecting the cables 14 which also carry the signal to their respective second cable ends 20b,c,d,e.

Each signal meter 34 is configured to receive the signal and to measure the respective received signal amplitude of the signal when received on the respective second cable end portion 20 of the cable 14 to which the signal meter 34 is connected. As the signal is transferred from the connected cable 14a to the other cables 14b,c,d,e, the amplitude of the signal is diminished as the signal must pass through the ground connector 30 during the transfer, which, also serving as a ground, diminishes the amplitude of the signal. At the same time, the path for the signal from the respective first cable end portion 18a to the respective second cable end portion 20a of the connected cable 14a is more direct than for the other cables 14b,c,d,e. Accordingly, the respective received signal amplitude of the signal is greater at the respective second end portion 20a of the connected cable 14a than at the respective second end portions 20,b,c,d,e of the other cables 14,b,c,d,e. Thus, by measuring the respective received signal amplitude of the signal at all respective second end portions 20 of the cables 14, the connected cable 14a can be remotely identified by comparing the respective received signal amplitude at the respective second cable end portions 20, the respective second cable end portion 20a of the connected cable 14a having the greatest respective received signal amplitude.

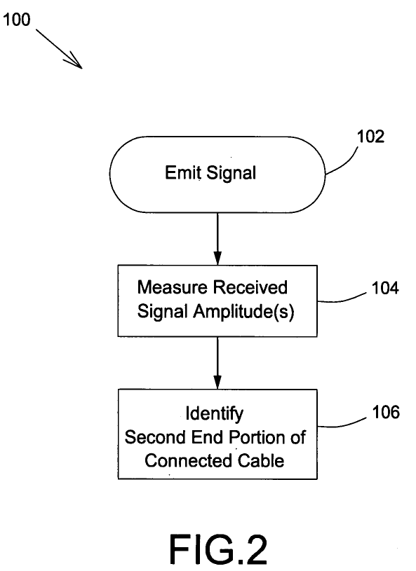

Based on the foregoing, and referring now to FIG. 2 in conjunction with FIG. 1, a method, shown generally as 100, for identifying the connected cable 14a connected to the selected antenna 16, at the respective second end portion 20a thereof is now described. To identify the connected cable 14a connected to the selected antenna 16a from the respective second end portion 20a thereof, the signal is emitted at the respective first cable end 18a thereof, at step 102. Next, at step 104, the respective received signal amplitude of the signal is measured at the respective second cable end portions 20 of all of the cables 14. Proceeding to step 106, the connected cable 14a, and specifically the respective second cable end portion 20a thereof, is identified by comparing the respective received signal amplitudes for the signal at all of the respective second cable end portions 20 to identify the respective second cable end portion 20 at which the respective received signal amplitude is greatest, i.e. greater than the respective received signal amplitude received at the respective second cable end portion 20 of any other cable 14. The cable 14 at which the received respective signal amplitude at the respective second end portion 20 is greatest is the connected cable 14, shown as cable 14a in FIG. 1.

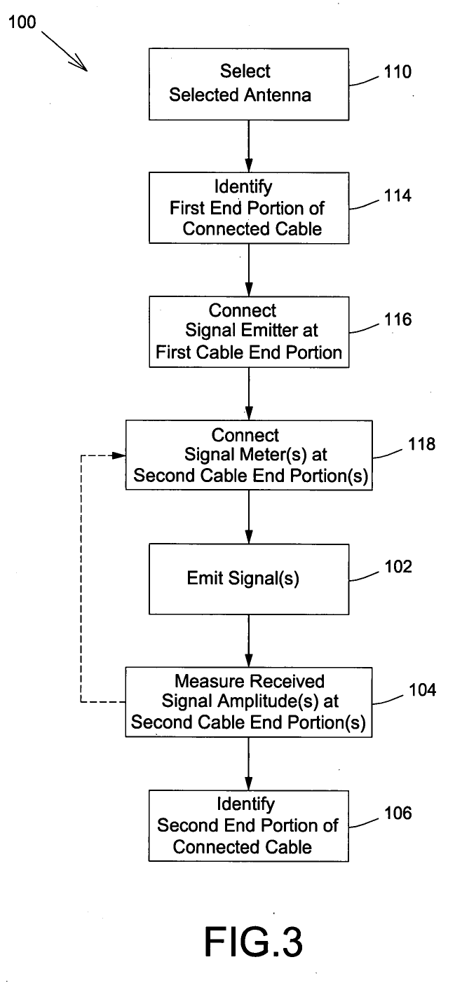

To better aid the reader in understanding the system 10 and the method 100 for identifying the connected cable 14a, reference is now made to FIG. 3, in conjunction with FIGS. 1 and 2. As shown in FIG. 3, prior to emitting the signal at step 102, an antenna 16 is selected, at step 110, as the selected antenna 16a. Then, at step 114, the connected cable 14 connected to the selected antenna 16 is identified. However, if a cable 14 is not connected to the selected antenna 16 at the respective first cable end portion 18 thereof, then a cable 14, preferably not already so connected to a different antenna 16, may be selected, and thereby identified, at step 114 for connection to the selected antenna as the connected antenna 14. For example, referring to FIG. 1, if antenna 16a is selected, then cable 14a would be identified as the connected cable 14 at step 114. Alternatively, if antenna 16b is selected, then, preferably, one of cables 16b,d, or e would be selected for connection thereto as the connected cable at step 114. Once the selected antenna, shown as 16a in FIG. 1, and the connected cable therefor, shown as 14a in FIG. 1, are identified, then the signal emitter 32 is connected, at step 116, to the respective first cable end portion 18a of the connected cable 14a connected to the selected antenna 16a.

Once the signal emitter 32 has been connected to the connected cable, shown as 14a in FIG. 1, a signal meter 34 is connected to the respective second cable end portion 20 of at least one of the cables 14 at step 118. Then, at step 102, the signal is emitted from the signal emitter 32. At step 104, using the signal meter 34, the respective received signal amplitude of the signal at the respective second cable end portion 18 to which the signal meter 28 is connected is measured. Steps 118, 102, and 104 are repeated until the respective received signal amplitude of the signal at the respective second cable end portion 18 for all of the cables 14 has been measured. It should be noted that, if desired, each respective cable end portion 20 may have a respective signal meter 28 connected thereto at step 118. In this case, steps 118, 102, and 104 need only be performed once, as the respective received signal amplitude for the signal can be measured at all respective second cable end portions 20 simultaneously. Alternatively, when all of the respective cable second end portions 20 do not have a signal meter 34 connected thereto when the signal is emitted, such as when there is only one signal meter 34 available for attachment to the respective second cable end portions 20, then steps 118, 102, and 104 must be repeated, using identical signals, until the respective received signal amplitude has been successively measured at all respective second cable end portions 20. Once the respective received signal amplitude has been measured at all respective second cable end portions 20, then the connected cable 14, and specifically the respective second cable end portion 20 thereof, shown as 14a and 20a in FIG. 1, at step 106 by identifying the cable for which the received signal amplitude is greatest at the respective second cable end portion 20 thereof. The method 10 may be repeated for each antenna 16 present to identify the connected cables 14 for all of the antennas 16.

The signal emitter 32 may be of any type that is capable of emitting a signal from the first cable end portion 18a of the connected cable 14a to the respective second cable end portions 20 of all the cables 14. Similarly, the signal may be of any frequency and amplitude, provided the signal may be carried by the cables 14 from the respective first end of the connected cable 14 to the respective second ends of all the cables 14. However, in general, a high frequency signal, between one Megahertz and one hundred Megahertz (1-100 MHz) is preferred. Further, the system 10 and method 100 may be used at any time. Ideally, when used in a telecommunications network context, the system 10 and method 100 are deployed during a period of preferably high network traffic, such as between 6 a.m. and 8 p.m., thereby minimizing the impact of technician labor costs required.

While a specific embodiment has been described, those skilled in the art will recognize many alterations that could be made within the spirit of the invention, which is defined solely according to the following claims.

I claim:

1. A method for remotely identifying a connected cable among a plurality of cables having respective first cable end portions situated proximal a selected antenna and generally opposed second cable end portions connected to a communication network for communication service therealong and being interconnected to one another by at least one ground connector connected to each cable, the connected cable being connected on the respective first end portion thereof to the selected antenna, the method comprising the steps of:
a) emitting at least one signal on the respective first end portion of the connected cable, said signal being transferred therefrom to the other cables at the ground connector and carried by all cables to their respective second cable end portions;
b) for each cable, measuring a respective received signal amplitude of said signal at the respective second cable end portion thereof, said respective received signal amplitude for each cable being diminished as said signal passes through the ground connector; and
c) identifying the connected cable at said respective second cable end portion thereof as the cable for which said respective received signal amplitude is greatest, said signal traveling on a more direct path on the connected cable from said first respective cable end portion through the ground connector to said second respective cable end portion thereof than on the other cables, the respective received signal amplitude being thereby diminished less than for the other cables.

2. The method of claim 1, further comprising, prior to step a), the step of:
connecting a signal emitter configured for emitting said signal to one of the connected cable and the selected antenna in proximity to said first end portion of the connected cable, said signal being emitted by said signal emitter at step a).

3. The method of claim 1, further comprising, prior to step a), the step of
connecting a respective signal meter configured for reading said respective received signal amplitude to the respective second cable end portion of each cable;
and wherein step b) includes
measuring the respective received signal amplitude at the respective second cable end portion of the cable to which said respective signal meter is connected with said respective signal meter.

4. The method of claim 1, wherein step b) includes:
successively connecting a signal meter configured for reading said respective received signal amplitude to the respective second cable end portion of each cable.

5. The method of claim 1, wherein said signal is a high frequency signal.

6. The method of claim 1, wherein the selected antenna is selected from a plurality of antennas situated proximal said first cable ends.

7. The method of claim 6, wherein each cable is connected, therefor at the respective first cable end portion thereof, to a respective one of the antennas as the respective connected cable therefore.

8. The method of claim 7, wherein each antenna is sequentially selected as the selected antenna and steps a), b) and c) are performed therefor, thereby permitting identification of the respective connected cable for each antenna.

9. The method of claim 1, wherein the selected antenna is connected to a wireless telephone network, said method being executed during a period of traffic for said wireless network, without communication service interruption.

10. The method of claim 9, wherein said method is executed during a period of high traffic service for said wireless network.

11. The method of claim 1, wherein the plurality of cables extend through a structure having a top end and a generally opposed bottom end, the respective first cable end portions being situated proximal said top end upon which said selected antenna is mounted and the respective second cable end portions being situated proximal said bottom end, said step a) being performed at said top end and said steps b) and c) being performed at said bottom end.

12. A system for remotely identifying a connected cable of a plurality of cables having respective first cable end portions situated proximal a selected antenna and generally opposed second cable end portions connected to a communication network for communication service therealong and being interconnected to one another by at least one ground connector connected to each cable, said connected cable being connected on said respective first end portion thereof to the selected antenna, said system comprising:
a signal emitter for emitting a signal on the respective first end portion of the connected cable, said signal being transferred therefrom to each other cable at the ground connector; and
a signal meter connectable to each cable for measuring a respective received signal amplitude for said signal on the respective second cable end portion thereof, the cable for which the respective received signal amplitude being the connected cable, wherein said connected cable provides a more direct path from said first respective cable end portion to said second respective cable end portion and said respective received signal amplitude for each cable is diminished as said signal is transferred thereto at the ground connector, the connected cable being identified as the cable for which said respective receiving signal amplitude is greatest.
